(19) United States
(12) Patent Application Publication
(10) Pub. No.: US 2026/0323932 A1
(43) Pub. Date: Oct. 15, 2026

(54) SEMICONDUCTOR DEVICE INCLUDING AN INSULATING LINER

(71) Applicant: Samsung Electronics Co., Ltd., Suwon-si (KR)

(72) Inventors: Sunmi Lee, Suwon-si (KR); Jinwoo Han, Suwon-si (KR)

(21) Appl. No.: 19/463,927

(22) Filed: Jan. 29, 2026

(30) Foreign Application Priority Data
Mar. 4, 2025 (KR) 10-2025-0027605

(51) Int. Cl. H10B 12/00

(52) U.S. Cl. CPC H10B 12/50; H10B 12/30

(57) ABSTRACT

A semiconductor device includes a first structure including a memory cell, and a routing lower structure electrically connected to the memory cell, a second structure vertically overlapping the first structure, including a peripheral circuit, and further including a semiconductor body, a device isolation region defining a peripheral active region on the semiconductor body, a peripheral transistor in the peripheral active region, a through-insulating pattern extending into the semiconductor body, an insulating liner between the semiconductor body and the through-insulating pattern, and a routing peripheral structure electrically connected to the peripheral transistor on the semiconductor body; and a routing through-via extending into the through-insulating pattern and electrically connected to the routing peripheral structure.

### CROSS-REFERENCE TO RELATED APPLICATION(S)

This application claims benefit of priority under 35 U.S.C. §119 to Korean Patent Application No. 10-2025-0027605 filed on Mar. 4, 2025 in the Korean Intellectual Property Office, the disclosure of which is incorporated herein by reference in its entirety.

### BACKGROUND

Research into reducing a size of elements included in a semiconductor device and improving performance thereof has been conducted. For example, in a DRAM, research to reliably and stably form elements having a reduced size has been conducted, but as the sizes of elements are reduced, performance of a semiconductor device may deteriorate.

### SUMMARY

Aspects of the present disclosure relate to a semiconductor device and a method of manufacturing the same.

An example implementation of the present disclosure is to provide a semiconductor device having improved reliability and performance.

According to an example implementation of the present disclosure, a semiconductor device includes a first structure including a memory cell, a routing lower structure electrically connected to the memory cell, and a first insulating structure covering the routing lower structure; a second structure vertically overlapping the first structure and including a peripheral circuit, and further including a semiconductor body, a backside insulating layer below the semiconductor body, a device isolation region defining a peripheral active region on the semiconductor body, a through-insulating pattern including a first pattern portion penetrating the semiconductor body, an insulating liner including a first liner portion disposed between the semiconductor body and the first pattern portion of the through-insulating pattern, a peripheral transistor including a first peripheral source/drain disposed in the peripheral active region, a second peripheral source/drain, a peripheral channel region between the first and second peripheral sources/drains, and a peripheral gate disposed on the peripheral channel region, a routing peripheral structure electrically connected to the peripheral transistor on the semiconductor body, and a second insulating structure covering the routing peripheral structure; and a routing connection structure electrically connecting the routing lower structure of the first structure to the routing peripheral structure of the second structure, wherein the routing connection structure includes through-vias penetrating the semiconductor body.

According to an example implementation of the present disclosure, a semiconductor device includes a first structure including a memory cell array region and a staircase region, and further including channel structures extending in a first horizontal direction on the memory cell array region and spaced apart from each other in a second horizontal direction intersecting the first horizontal direction, an insulating layer between the channel structures, bitlines extending in a vertical direction on the memory cell array region and in contact with a first end of each of the channel structures, at least one gate electrode extending in the second horizontal direction and surrounding the channel structures, data storage structures in contact with second ends of the channel structures opposing the first ends of the channel structures and spaced apart from each other in the second horizontal direction, a plate electrode connected to the data storage structures and extending in the second horizontal direction and the vertical direction, and a routing lower structure electrically connected to the bitlines; a second structure vertically overlapping the first structure, including a peripheral circuit, and further including a semiconductor body, a backside insulating layer below the semiconductor body, a device isolation region defining a peripheral active region on the semiconductor body, a through-insulating pattern penetrating the semiconductor body, an insulating liner between the semiconductor body and the through-insulating pattern, a peripheral transistor including a first peripheral source/drain disposed in the peripheral active region, a second peripheral source/drain, a peripheral channel region between the first and second peripheral sources/drains, and a peripheral gate disposed on the peripheral channel region, and a routing peripheral structure electrically connected to the peripheral transistor on the semiconductor body, and a second insulating structure covering the routing peripheral structure; and a routing through-via electrically connecting the routing lower structure of the first structure to the routing peripheral structure of the second structure, and penetrating the through-insulating pattern.

According to an example implementation of the present disclosure, a semiconductor device includes a first structure including a memory cell, and a routing lower structure electrically connected to the memory cell, a second structure vertically overlapping the first structure, including a peripheral circuit, and further including a semiconductor body, a device isolation region defining a peripheral active region on the semiconductor body, a peripheral transistor in the peripheral active region, a through-insulating pattern penetrating the semiconductor body, an insulating liner between the semiconductor body and the through-insulating pattern, and a routing peripheral structure electrically connected to the peripheral transistor on the semiconductor body; and a routing through-via penetrating the through-insulating pattern and electrically connected to the routing peripheral structure.

### BRIEF DESCRIPTION OF DRAWINGS

The above and other aspects, features, and advantages of the present disclosure will be more clearly understood from the following detailed description, taken in combination with the accompanying drawings.

FIG. 1A is a plan diagram illustrating a semiconductor device according to an example implementation of the present disclosure.

FIG. 1B is a vertical cross-sectional diagram illustrating the semiconductor device illustrated in FIG. 1A taken along line I-I’.

FIG. 1C is an enlarged diagram illustrating the semiconductor device illustrated in FIG. 1B.

FIG. 1D is a vertical cross-sectional diagram illustrated in FIG. 1A taken along line II-II’.

FIG. 1E is an enlarged diagram illustrating the semiconductor device illustrated in FIG. 1D.

FIG. 2 is an enlarged diagram illustrating a portion of a semiconductor device according to an example implementation of the present disclosure.

FIG. 3A is a vertical cross-sectional diagram illustrating a semiconductor device according to an example implementation of the present disclosure.

FIG. 3B is an enlarged diagram illustrating the semiconductor device illustrated in FIG. 3A.

FIG. 4 is an enlarged diagram illustrating a portion of a semiconductor device according to an example implementation of the present disclosure.

FIG. 5A is a vertical cross-sectional diagram illustrating a semiconductor device according to an example implementation of the present disclosure.

FIG. 5B is an enlarged diagram illustrating the semiconductor device illustrated in FIG. 5A.

FIG. 6A is a vertical cross-sectional diagram illustrating a semiconductor device according to an example implementation of the present disclosure.

FIG. 6B is an enlarged diagram illustrating the semiconductor device illustrated in FIG. 6A.

FIGS. 7A, 7B, 7C, 7D, 7E, 7F and 7G are vertical cross-sectional diagrams illustrating processes of a method of manufacturing a semiconductor device in order according to an example implementation of the present disclosure.

FIGS. 8A, 8B, 8C, 8D, 8E and 8F are vertical cross-sectional diagrams illustrating processes of a method of manufacturing a semiconductor device in order according to an example implementation of the present disclosure.

### DETAILED DESCRIPTION

Hereinafter, implementations of the present disclosure will be described as follows with reference to the accompanying drawings.

The terms such as “upper,” “upper portion,” “upper surface,” “lower,” “lower portion,” “lower surface,” “side surface,” “upper end,” and “lower end” may be referred to based on the drawings, unless otherwise indicated. The terms such as “upper portion,” “intermediate portion,” and “lower portion,” or the like, may be replaced with other terms, for example, “first,” “second,” and “third,” and may be used to describe elements in the implementations. The terms such as “first,” “second,” and “third” may be used to describe various elements, but the elements are not limited to the terms, and a “first component” may be denoted as a “second component.”

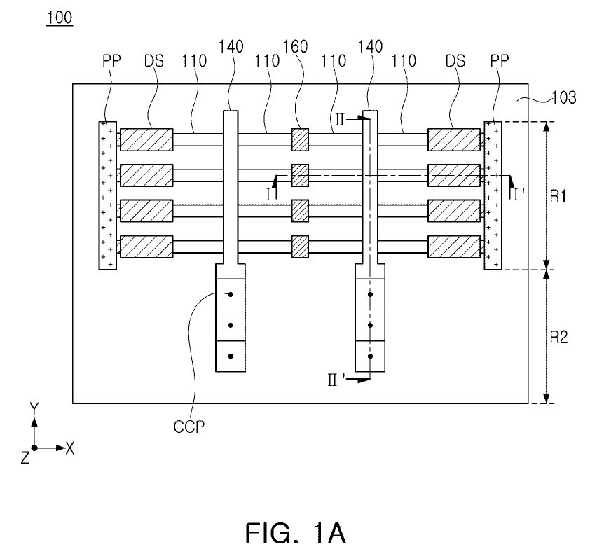

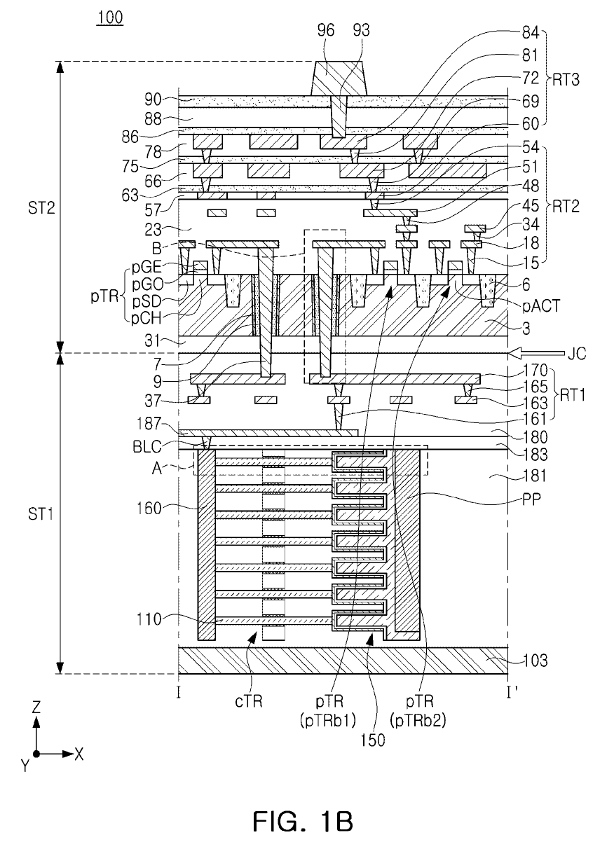

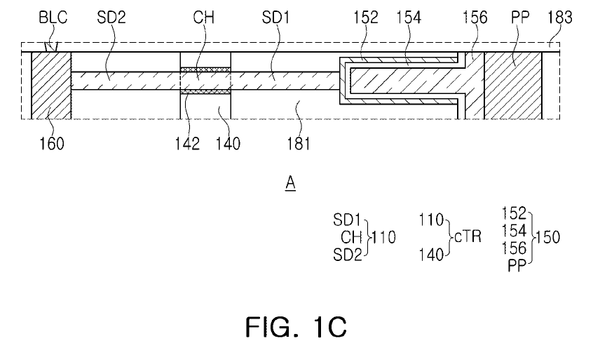

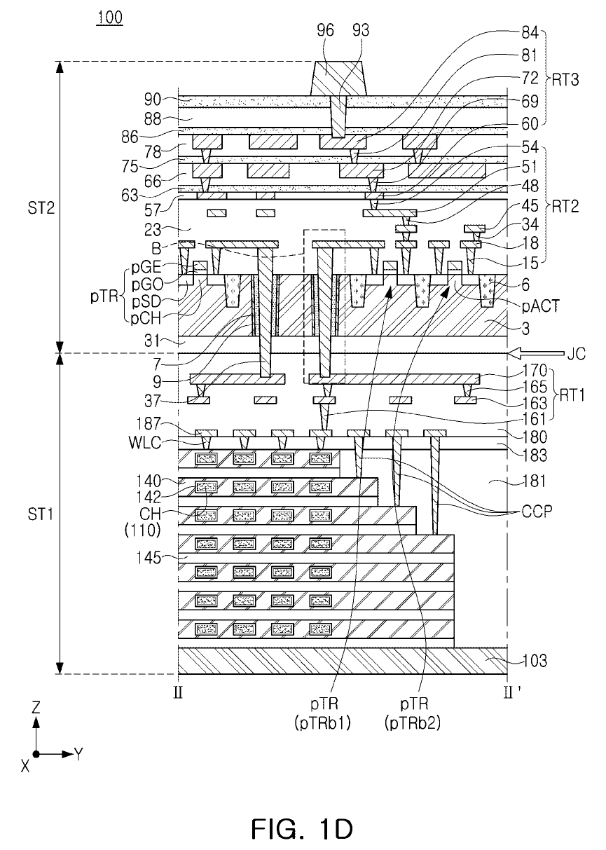

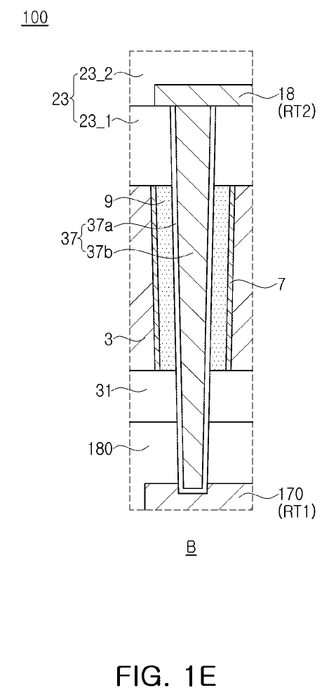

FIG. 1A is a plan diagram illustrating a semiconductor device according to an example implementation.

FIG. 1B is a vertical cross-sectional diagram illustrating the semiconductor device illustrated in FIG. 1A taken along line I-I’.

FIG. 1C is an enlarged diagram illustrating the semiconductor device illustrated in FIG. 1B.

FIG. 1D is a vertical cross-sectional diagram illustrated in FIG. 1A taken along line II-II’.

FIG. 1E is an enlarged diagram illustrating the semiconductor device illustrated in FIG. 1D.

Referring to FIGS. 1A-1E, a semiconductor device 100 according to an example implementation may include a first structure ST1 and a second structure ST2 vertically overlapping the first structure ST1. The second structure ST2 may be disposed on the first structure ST1.

In an example implementation, the first structure ST1 may be configured as a first chip structure including memory cells, and the second structure ST1 may be configured as a second chip structure including peripheral circuits for operating the memory cells. The first structure ST1 and the second structure ST2 may be formed by bonding by a bonding process, such as a wafer bonding process. Accordingly, the first structure ST1 may be in contact with and bonded to the second structure ST2.

Each of the memory cells may include a data storage structure which may function as a cell transistor CTR and data storage. In a memory such as a DRAM, the data storage structure may be configured as a cell capacitor for storing data.

The first structure ST1 may include a substrate 103 including a memory cell array region R1 and a staircase region R2, active layers 110 disposed on the substrate 103, gate electrodes 140, vertical conductive patterns 160 extending in a vertical direction, and a capacitor structure 150. In an example implementation, at least one of the gate electrodes 140 may be referred to as a wordline, and the vertical conductive patterns 160 may be referred to as a bitline.

Cell transistors cTR disposed between the vertical conductive patterns 160 and the capacitor structures 150 may be disposed on the memory cell array region R1 of the substrate 103. Gate electrodes 140 extending from the memory cell array region R1 by different lengths may be disposed on the staircase region R2 of the substrate 103. The memory cell array region R1 and the staircase region R2 may be disposed side by side in the Y-direction. In an example implementation, the memory cell array region R1 may be referred to as a first region, and the staircase region R2 may be referred to as a second region.

The substrate 103 may include a semiconductor material, such as a group IV semiconductor, a group III-V compound semiconductor, or a group II-VI compound semiconductor. For example, the group IV semiconductor may include silicon, germanium, or silicon-germanium. The substrate 103 may further include impurities. The substrate 103 may be configured as a silicon substrate, a silicon-on-insulator (SOI) substrate, a germanium substrate, a germanium on insulator (GOI) substrate, a silicon-germanium substrate, or a substrate including an epitaxial layer.

The active layers 110, the gate electrodes 140, and the gate dielectric layers 142 may be included in the cell transistor cTR.

The active layers 110 may be disposed on the substrate 103 and may extend in the X-direction. The active layers 110 may be spaced apart from each other in the Y-direction and the Z-direction. In the plan diagram, the active layers 110 may have a line shape, a bar shape, or a pillar shape intersecting the gate electrodes 140 and extending in the X-direction. In an example, the active layers 110 may include a semiconductor material, such as silicon, germanium, or silicon-germanium.

Each of the active layers 110 may include a first source/drain region SD1, a channel region CH and a second source/drain region SD2, sequentially arranged in the X-direction. The channel region CH may be disposed between the first source/drain region SD1 and the second source/drain region SD2. The second source/drain region SD2 may be in contact with the vertical conductive pattern 160 and may be electrically connected to the vertical conductive pattern 160. The first source/drain region SD1 may be in contact with the first electrode 152 of the capacitor structure 150 and may be electrically connected to the first electrode 152. The channel region CH may be surrounded by the gate electrode 140. For example, an upper surface, a lower surface and side surfaces of the channel region CH may be surrounded by the gate electrode 140. When the active layer 110 is formed of a semiconductor material, each of the first source/drain region SD1 and the second source/drain region SD2 may include impurities, and the impurities may have a N-type or P-type conductivity.

The gate electrodes 140 may be disposed on the substrate 103 and may extend horizontally in the Y-direction. The gate electrodes 140 may be spaced apart from each other in the X-direction and the Z-direction. The gate electrodes 140 may be disposed between the channel regions CH of the adjacent active layers 110 in the vertical direction. The gate electrodes 140 may partially overlap the first source/drain regions SD1 and the second source/drain regions SD2 of the active layers 110 in the vertical direction. In the plan diagram, the gate electrodes 140 may have a line shape, a bar shape, or a pillar shape extending in the Y-direction.

The gate electrodes 140 may be vertically stacked and spaced apart from each other on the memory cell array region R1, may extend from the memory cell array region R1 to the staircase region R2 by different lengths and may form a step structure of a staircase shape.

Contacts may be formed on the gate electrodes 140. For example, wordline contacts WLC may be disposed on an uppermost gate electrode among the gate electrodes 140. For example, gate pads may be formed on an upper surface of a second gate electrode disposed below the uppermost gate electrode, an upper surface of a third gate electrode, and an upper surface of a fourth gate electrode among the gate electrodes 140. Contact plugs CCP may be disposed on the gate pads.

The gate electrodes 140 may include a conductive material, and the conductive material may include at least one of a doped semiconductor material (e.g., doped silicon, doped germanium, or the like), a conductive metal nitride (e.g., titanium nitride, tantalum nitride, tungsten nitride, or the like), a metal (e.g., tungsten, titanium, tantalum, cobalt, aluminum, ruthenium, or the like), and a metal-semiconductor compound (e.g., tungsten silicide, cobalt silicide, titanium silicide, or the like). In an example implementation, the gate electrodes 140 may be disposed on an upper surface and a lower surface of each active layer 110, and two gate electrodes 140 adjacent to each active layer 110 may be included in one wordline.

In an example implementation, the gate electrode 140 may be disposed in a gate all around structure surrounding the active layer 110. For example, the gate electrode 140 may surround the upper surface, the lower surface and side surfaces of the active layer 110.

The gate dielectric layer 142 may cover an upper surface, a lower surface, and a side surface of each of the channel structures 110. The gate dielectric layer 142 may include at least one of silicon oxide, silicon nitride, a low-κ material, and a high-κ material. The high-κ material may refer to a dielectric material having a dielectric constant higher than that of silicon oxide, and the low-κ material may indicate a dielectric material having a dielectric constant lower than that of silicon oxide. The high-κ material may be, for example, a metal oxide or a metal oxide-nitride.

The high-κ material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In example implementations, the gate dielectric layer 142 may be formed as a single layer or multiple layers formed of the materials described above.

The first structure ST1 may further include interlayer insulating layers 145 between gate electrodes 140 stacked and spaced apart from each other in the vertical direction (Z-direction). The interlayer insulating layers 145 may spatially isolate and electrically insulate adjacent gate electrodes 140 in the vertical direction (Z-direction). The interlayer insulating layers 145 may include at least one of an insulating material, for example, silicon nitride, silicon oxynitride, and silicon oxycarbide.

The capacitor structure 150 may be configured as a memory cell capacitor for storing data in a memory such as a DRAM. Each of the capacitor structures 150 may include first electrodes 152, a second electrode 156, and a dielectric layer 154 between the first electrodes 152 and the second electrode 156.

The first structure ST1 may further include insulating layers 181 and 183 covering gate electrodes 140, vertical conductive patterns 160 and capacitor structures 150, contact plugs BLC and WLC penetrating the insulating layer 183, and an insulating layer 183 disposed on the conductive line 187 and connected to the contact plugs BLC and WLC. The conductive line 187 may extend in the first direction (X-direction) on the insulating layer 183. The contact plugs BLC and WLC may include wordline contacts WLC electrically connecting the conductive line 187 to the gate electrodes 140 (or wordline) and bitline contacts BLC electrically connecting the conductive line 187 to the vertical conductive patterns 160 (or bitline).

The first structure ST1 may further include a routing lower structure RT1. The routing lower structure RT1 may include first vertical vias 161 on the conductive line 187, first horizontal portions 163 on the first vertical vias 161, second vertical vias 165 on the first horizontal portions 160, and second horizontal portions 170 on the second vertical vias 165. The first and second horizontal portions 163, 170 may be configured as redistributions for routing, and the vertical vias 161 and 165 may be configured as conductive vias. The routing lower structure RT1 may be electrically connected to the memory cell.

The first structure ST1 may further include an insulating structure 180 covering the routing lower structure RT1. The insulating structure 180 may be referred to as the first insulating structure. The insulating structure 180 may include at least one of an insulating material, for example, silicon nitride, silicon oxynitride, and silicon oxycarbide.

The second structure ST2 may further include a semiconductor body 3 including peripheral active regions pACT, a device isolation region 6 defining the peripheral active regions pACT on the semiconductor body 3, and through-insulating patterns 9 penetrating the semiconductor body 3. The device isolation region 6 may define side surfaces of the peripheral active regions pACT. The device isolation region 6 may be formed of an insulating material. The through-insulating patterns 9 may have lower surfaces coplanar with a lower surface of the semiconductor body 3, and upper surfaces coplanar with an upper surface of the device isolation region 6. The through-insulating patterns 9 may include at least one of a low-κ dielectric, silicon oxide, silicon nitride, SiBN, SiCN, SiON, SiOCN, doped silicon oxide, or doped silicon nitride.

The semiconductor body 3 may include a semiconductor material, for example, a group IV semiconductor, a group III-V compound semiconductor, or a group II-VI compound semiconductor. For example, the group IV semiconductor may include silicon, germanium, or silicon-germanium. In an example implementation, the semiconductor body 3 may have an N-type conductivity or may have a P-type conductivity. For example, the semiconductor body 3 may have a P-type conductivity. The semiconductor body 3 may include, for example, a silicon substrate having a P-type conductivity.

The second structure ST2 may further include an insulating liner 7 between the semiconductor body 3 and the through-insulating patterns 9. The insulating liner 7 may have a lower surface coplanar with a lower surface of the through-insulating pattern 9, and an upper surface coplanar with an upper surface of the through-insulating pattern 9. The insulating liner 7 may surround at least a portion of the routing connection structure 37. The insulating liner 7 may include an insulating material different from that of the through-insulating pattern 9. The insulating liner 7 may include a fixed charge film. For example, the insulating liner 7 may include a fixed charge film having a negative fixed charge. The fixed charge film may include a material selected from a group consisting of, for example, hafnium oxide (HfO₂), zirconium oxide (ZrO₂), aluminum oxide (Al₂O₃), cerium oxide (CeO₂), gadolinium oxide (Gd₂O₃), silicon nitride (AlN), and silicon nitride (Si₃N₄).

The second structure ST2 may further include peripheral transistors pTR disposed on the semiconductor body 3, a first routing peripheral structure RT2, and a second routing peripheral structure RT3.

Each of the peripheral transistors pTR may include peripheral source/drain regions pSD disposed in the peripheral active region pACT, a peripheral channel region pCH between the peripheral source/drain regions pSD, and a peripheral gates pGO and pGE on the peripheral channel region pCH. The peripheral gates pGO and pGE may include a peripheral gate dielectric layer pGO and a peripheral gate electrode pGE on the peripheral gate dielectric layer pGO. In an example implementation, each of the peripheral source/drain regions pSD may be referred to as first and second peripheral source/drain regions, respectively. The peripheral transistors pTR may include NMOS transistors and PMOS transistors. When the peripheral transistor pPTR is configured as an NMOS transistor, the peripheral source/drain regions pSD may have an N-type conductivity, and when the peripheral transistor pTR is configured as a PMOS transistor, the peripheral source/drain regions pSD may have P-type conductivity.

In an example implementation, the first and second peripheral transistors pPTRb1 and pPTRb2 may be different types of transistors. For example, in an example implementation, the first peripheral transistor pPTRb1 may be configured as an NMOS transistor, and the second peripheral transistor pPTRb2 may be configured as a PMOS transistor. For example, in an example implementation, the first peripheral transistor pPTRb1 may be configured as a PMOS transistor, and the second peripheral transistor pPTRb2 may be configured as an NMOS transistor.

The first routing peripheral structure RT2 may include vertical plugs 15, first horizontal portions 18 disposed at a level higher than a level of the vertical plugs 15, first vertical vias 34 on the first horizontal portions 18, second horizontal portions 45 disposed at a level higher than a level of the first vertical vias 34, second vertical vias 48 on the second horizontal portions 45, third horizontal portions 51 disposed at a level higher than a level of the second vertical vias 48, and third vertical vias 54 on the third horizontal portions 51. The horizontal portions 18, 45, and 51 may be interconnections for routing.

The second routing peripheral structure RT3 may include first horizontal portions 60, first vertical vias 69 on the first horizontal portions 60, second horizontal portions 72 on the first vertical vias 69, third vertical vias 81 on the second horizontal portions 72, and fourth horizontal portions 84 on the third vertical vias 81. The horizontal portions 60, 72, and 84 may be peripheral interconnections for routing.

The second structure ST2 may further include upper vias 93 on the second horizontal portions 84 and upper interconnections 96 on the upper vias 93.

The second structure ST2 may include a lower insulating structure 23 covering the first routing peripheral structure RT2, and a first interlayer insulating layer 57, a first barrier insulating layer 63, a second interlayer insulating layer 66, a second barrier insulating layer 75, a third interlayer insulating layer 78, a third barrier insulating layer 86, a fourth interlayer insulating layer 88 and a fourth barrier insulating layer 90 stacked in order on the lower insulating structure 23. In an example implementation, the lower insulating structure 23 may be referred to as a second insulating structure. The first to fourth barrier insulating layers 63, 75, 86, and 90 may include

materials different from those of the first to fourth interlayer insulating layers 23, 66, 78, and 88. The first routing peripheral structure RT2 may be disposed in the lower insulating structure 23. The second routing peripheral structure RT3 may be disposed in the first interlayer insulating layer 57, the first barrier insulating layer 63, the second interlayer insulating layer 66, the second barrier insulating layer 75 and the third interlayer insulating layer 78. The upper vias 93 may penetrate the third barrier insulating layer 86, the fourth interlayer insulating layer 88 and the fourth barrier insulating layer 90. The upper interconnections 96 may be disposed on the fourth barrier insulating layer 90.

Each of the routing lower structure RT1, the first routing peripheral structure RT2, the second routing peripheral structure RT3, the upper vias 93 and the upper interconnections 96 may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, but an example implementation thereof is not limited thereto. Each of the routing lower structure RT1, the first routing peripheral structure RT2, the second routing peripheral structure RT3, the upper vias 93 and the upper interconnections 96 may include a single layer or multiple layers of the aforementioned materials.

The second routing peripheral structure RT3 may include a conductive material different from that of at least one of the routing lower structure RT1, the first routing peripheral structure RT2, the upper vias 93 and the upper interconnections 96. At least a portion of the routing lower structure RT1 may include a first conductive material, at least a portion of the first routing peripheral structure RT2 may include a second conductive material, at least a portion of the second routing peripheral structure RT3 may include a third conductive material, the upper vias 93 may include a fourth conductive material, and the upper interconnections 96 may include a fifth conductive material. The third conductive material may include copper, and at least one of the routing lower structure RT1, the first routing peripheral structure RT2, the upper vias 93 and the upper interconnections 96 may not include copper. The fifth conductive material may include a material different from the first, second, third and fourth conductive materials, for example, aluminum, and at least one of the first, second and fourth conductive materials may include tungsten or molybdenum.

The second structure ST2 may further include a backside insulating layer 31 covering a lower surface of the semiconductor body 3 and lower surfaces of the through-insulating patterns 9.

A lower surface of the backside insulating layer 31 may be bonded to an upper surface of the insulating structure 180. Accordingly, an upper surface of the first structure ST1 and a lower surface of the second structure ST2 may be bonded and may form a bonding surface JC.

The semiconductor device 100 may further include a routing connection structure 37 penetrating at least a portion of each of the first and second structures ST1 and ST2 and electrically connecting the routing lower structure RT1 to the first routing peripheral structure RT2.

The routing connection structure 37 may include a through-via penetrating the semiconductor body 3 or the through-insulating patterns 9. Accordingly, the routing connection structure 37 may be referred to as a through-via.

The routing connection structure 37 may penetrate the through-insulating patterns 9, may extend upwardly and may be connected to the first routing peripheral structure RT2. For example, the routing connection structure 37 may extend upwardly to penetrate the first portion 23_1 of the second insulating structure 23 and may be connected to the first routing peripheral structure RT2. The second portion 23_2 of the second insulating structure 23 may be disposed on the first portion 23_1 and may cover the first horizontal portion 18. An upper surface of the routing connection structure 37 may be at a level higher than a level of an upper surface of the semiconductor body 3 and a level of an upper surface of the through-insulating pattern 9.

The routing connection structure 37 may penetrate the through-insulating patterns 9, may extend downwardly and may be connected to the routing lower structure RT1. For example, the routing connection structure 37 may extend downwardly to penetrate the backside insulating layer 31 and the first insulating structure 180 and may be connected to the routing lower structure RT1.

A lower surface of the routing connection structure 37 may be at a level lower than a level of a lower surface of the semiconductor body 3 and a level of a lower surface of the through-insulating pattern 9.

Each of the through-vias may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, but an example implementation thereof is not limited thereto. Each of the through-vias may include a single layer or multiple layers formed of the conductive materials described above. For example, each of the through-vias may include a conductive pillar 37b and a conductive barrier layer 37a covering a side surface and a lower surface of the conductive pillar 37b.

According to an example implementation, by further including an insulating liner 7 between the through-insulating pattern 9 and the semiconductor body 3, the semiconductor device 100 having improved reliability and improved performance may be provided.

When a voltage is applied to the routing peripheral structure 37, an electric field may be formed due to a potential difference between the routing peripheral structure 37 and the semiconductor body 3 with the through-insulating pattern 9 interposed therebetween. Due to the electric field, a depletion region may be formed in a region of the semiconductor body 3 adjacent to the through-insulating pattern 9. Accordingly, an effective area of the semiconductor body 3 may be reduced.

In an example implementation, the semiconductor device 100 may further include the insulating liner 7 between the routing peripheral structure 37 and the semiconductor body 3, thereby reducing or preventing the formation of the depletion region, and accordingly, a decrease of the effective area of the substrate may be reduced or prevented. In an example implementation, the semiconductor body 3 may have a P-type conductivity, and the insulating liner 7 may include a fixed charge film having a negative fixed charge.

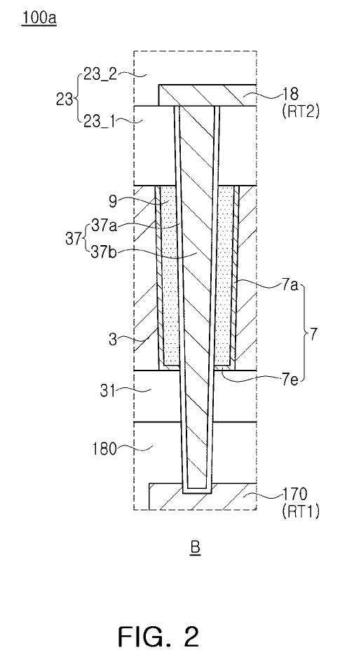

FIG. 2 is an enlarged diagram illustrating a portion of a semiconductor device according to an example implementation.

Referring to FIG. 2, the example implementation may be may be the same as or similar to the example described with reference to FIGS. 1A-1E, other than the configuration in which a portion in which the insulating liner 7 extends to a region between the through-insulating pattern 9 and the backside insulating layer 31 and is in contact with a side surface of the routing connection structure 37 is included.

In an example implementation, the insulating liner 7 may include a first liner portion 7a between the through-insulating pattern 9 and the semiconductor body 3, and a first extension portion 7e extending from an end of the first liner portion 7a to a region between a lower surface of the through-insulating pattern 9 and an upper surface of the backside insulating layer 31 and in contact with a side surface of the routing connection structure 37. The first extension portion 7e may, for example, be in contact with a side surface of the conductive barrier layer 37a.

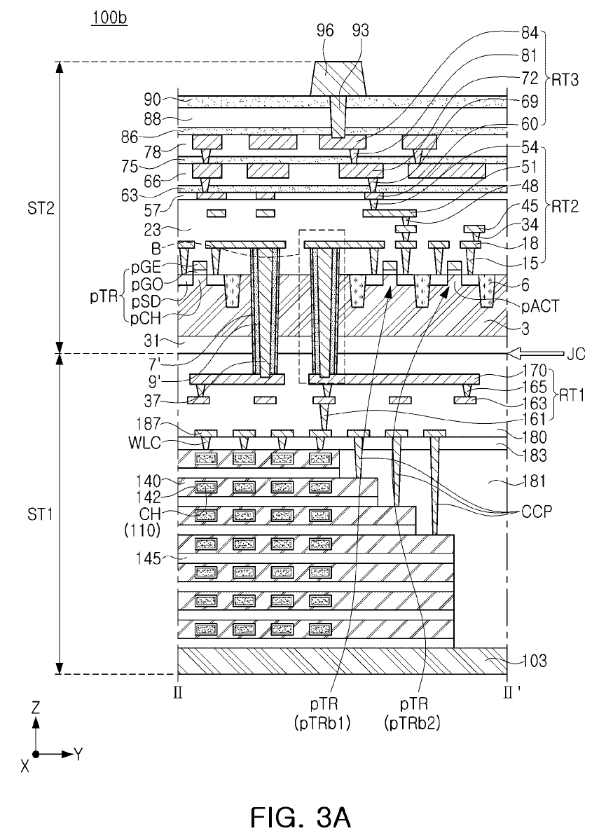

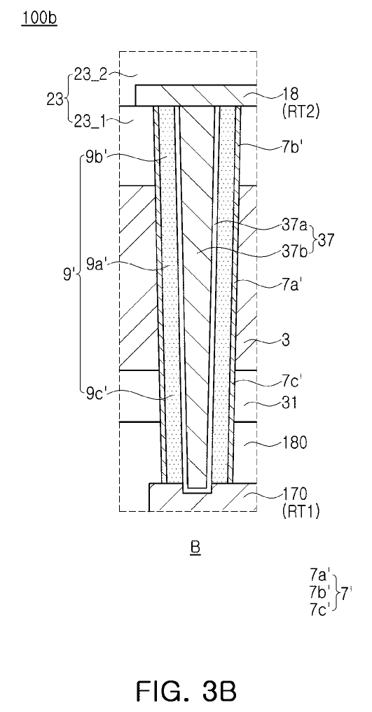

FIG. 3A is a vertical cross-sectional diagram illustrating a semiconductor device according to an example implementation.

FIG. 3B is an enlarged diagram illustrating the semiconductor device illustrated in FIG. 3A.

Referring to FIGS. 3A and 3B, the example implementation may be the same as or similar to the example implementation described with reference to FIGS. 1A-1E and 2, other than the configuration in which the semiconductor device 100b includes a through-insulating pattern 9’ extending upwardly and downwardly to be in contact with a routing lower structure RT1 and a first routing peripheral structure RT2.

In an example implementation, the through-insulating pattern 9 may include a first pattern portion 9a’ penetrating the semiconductor body 3, a 2-1 pattern portion 9b’ extending upwardly from an upper end of the first pattern portion 9a’ and in contact with the first routing peripheral structure RT2, and a 2-2 pattern portion 9c’ extending downwardly from a lower end of the first pattern portion 9a’ and in contact with the routing lower structure RT1. In an example

implementation, the 2-1 pattern portion 9b’ and the 2-2 pattern portion 9c’ may be referred to as a second pattern portion. Boundaries between the first pattern portion 9a’, the 2-1 pattern portion 9b’ and the 2-2 pattern portion 9c’ may not be distinct.

The routing lower structure RT1 may be surrounded by the first pattern portion 9a’, the 2-1 pattern portion 9b’ and the 2-2 pattern portion 9c’.

In an example implementation, the insulating liner 7’ may include a first liner portion 7a’ between the first pattern portion 9a’ and the semiconductor body 3, a 2-1 liner portion 7b’ extending upwardly from an upper end of the first liner portion 7a’ and in contact with a first routing peripheral structure RT2, and a 2-2 liner portion 7c’ extending downwardly from a lower end of the first liner portion 7a’ and in contact with a routing lower structure RT1. In an example implementation, the 2-1 liner portion 7b’ and the 2-2 liner portion 7c’ may be referred to as a second liner portion. A boundary between the first liner portion 7a’, the 2-1 liner portion 7b’ and the 2-2 liner portion 7c’ may not be distinct.

The routing lower structure RT1 may be surrounded by the first liner portion 7a’, the 2-1 liner portion 7b’ and the 2-2 liner portion 7c’.

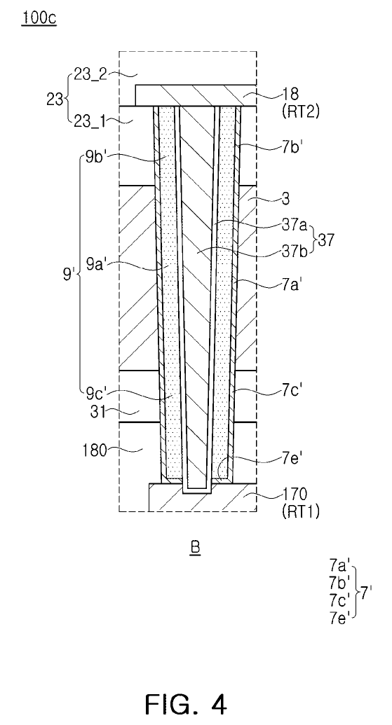

FIG. 4 is an enlarged diagram illustrating a portion of a semiconductor device according to an example implementation.

Referring to FIG. 4, the example implementation may be the same as or similar to the example implementation described with reference to FIGS. 1A-3B, other than the configuration in which a portion in which the insulating liner 7’ extends to a region between the through-insulating pattern 9’ and the horizontal portion 170 of the routing lower structure RT1 and is in contact with a side surface of the routing connection structure 37.

In an example implementation, the insulating liner 7’ in FIG. 4, as compared to the insulating liner 7’ described with reference to FIG. 3B, a second extension portion 7e’ extending from an end of a 2-2 liner portion 7c’ to a region between a lower surface of the through-insulating pattern 9 and an upper surface of the horizontal portion 170 of the routing lower structure RT1 and in contact with a side surface of the routing connection structure 37 may be further included.

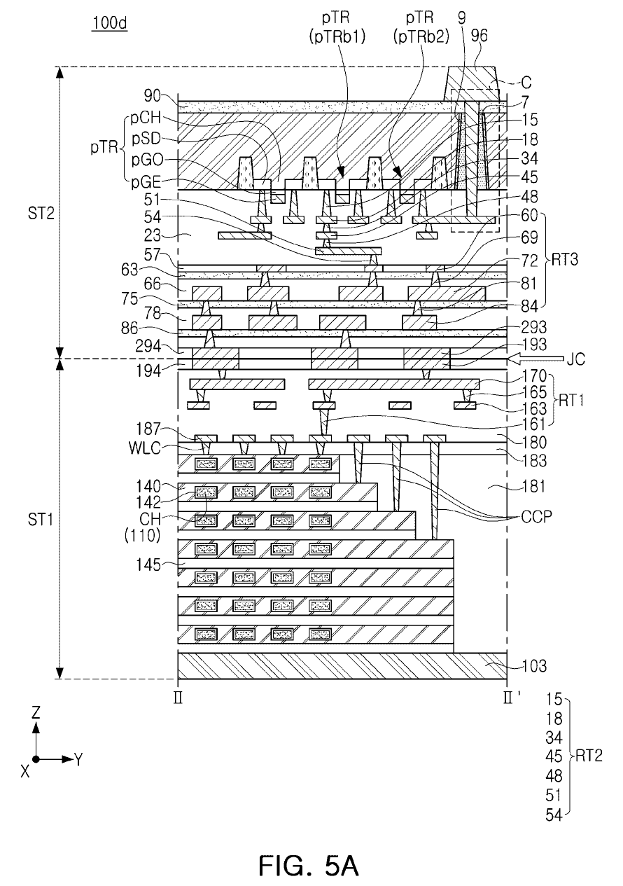

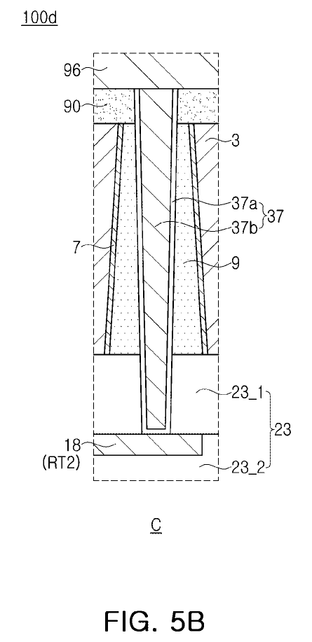

FIG. 5A is a vertical cross-sectional diagram illustrating a semiconductor device according to an example implementation.

FIG. 5B is an enlarged diagram illustrating the semiconductor device illustrated in FIG. 5A.

Referring to FIGS. 5A and 5B, the example implementation may be the same as or similar to the example implementation described with reference to FIGS. 1A-4, other than the configuration in which the first and second structures ST1 and ST2 are bonded to each other by hybrid bonding.

The first structure ST1 may include first bonding insulating layers 194 and first bonding metal layers 193 disposed on an upper portion of the first insulating structure 180. An upper surface of the first bonding insulating layers 194 and an upper surface of the first bonding metal layers 193 may be coplanar with each other.

The second structure ST2 may include second bonding insulating layers 294 and second bonding metal layers 293 disposed on a lower portion of the second insulating structure 23. A lower surface of the second bonding insulating layers 294 and a lower surface of the second bonding metal layers 293 may be coplanar with each other.

The first and second structures ST1 and ST2 may be bonded to each other by bonding between the first bonding insulating layers 194 and the second bonding insulating layers 294 and bonding between the first bonding metal layers 193 and the second bonding metal layers 293. The bonding between the first bonding metal layers 193 and the second bonding metal layers 293 may be copper (Cu)-copper (Cu) bonding, and the bonding between the first bonding insulating layers 194 and the second bonding insulating layers 294 may be dielectric-dielectric bonding such as SiCN-SiCN bonding.

In the example implementation, the routing connection structure 37 may be referred to as a through-via.

The through-via may electrically connect an upper interconnection 96 to a routing peripheral structure RT1. The through-via may penetrate the through-insulating pattern 9, may extend upwardly and may be connected to the upper interconnection 96, and may penetrate the through-insulating pattern 9, may extend downwardly and may be connected to the routing peripheral structure RT1.

From a cross-sectional perspective, slopes of the through-via and the insulating liner 7 may be in opposite directions. For example, a width of the through-via may increase in the vertical direction (Z-direction). A distance between the insulating liners 7 may decrease in the vertical direction (Z-direction).

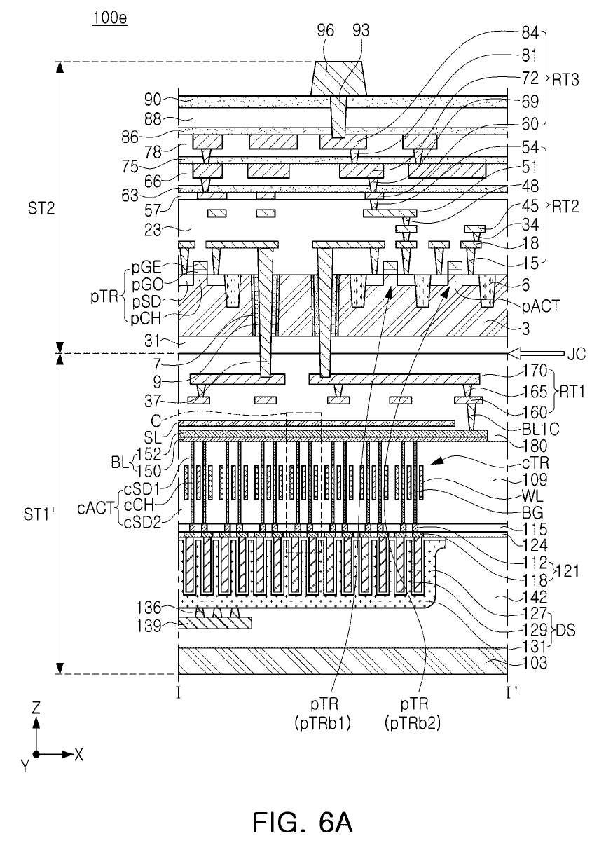

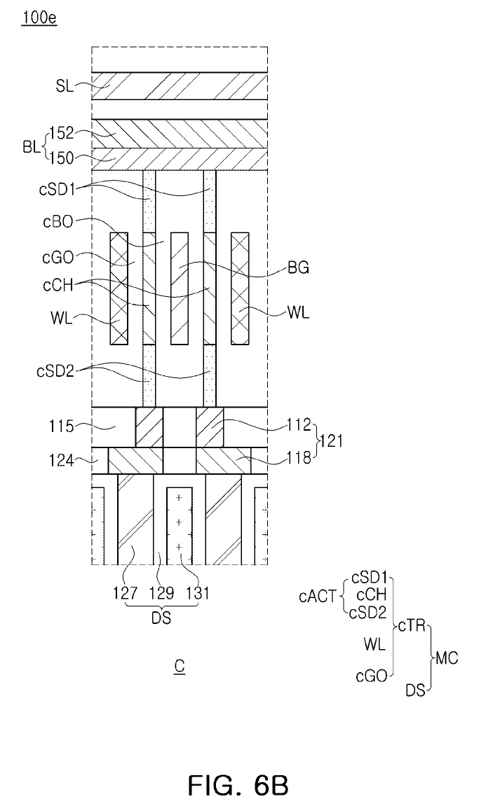

FIG. 6A is a vertical cross-sectional diagram illustrating a semiconductor device according to an example implementation.

FIG. 6B is an enlarged diagram illustrating the semiconductor device illustrated in FIG. 6A.

Referring to FIGS. 6A and 6B, a memory cell of the first structure ST1’ may be the same as or similar to the example implementation described with reference to FIGS. 1A-5, other than the configuration in which a memory cell of the first structure ST1 includes a transistor and a data storage structure of a different type and shape from those of the memory cell of the first structure ST1 described with reference to FIGS. 1A-1E.

In the example implementation, the first structure ST1’ may include a wordline WL and data storage structures DS disposed at a level lower than a level of the wordline WL.

In the example implementation, each of the data storage structures DS may include first electrodes 127 extending in the vertical direction Z, second electrodes 131 covering a side surface and a lower surface of each of the first electrodes 127, and a dielectric layer 129 between the first electrodes 127 and the second electrode 131.

The data storage structures DS may be cell capacitors for storing data in a memory such as DRAM, but an example implementation thereof is not limited thereto. For example, the data storage structures DS may be configured as a data storage structure of MRAM or a data storage structure of FeRAM.

In the example implementation, the first structure ST1’ may further include cell active patterns cACT.

Each of the cell active patterns cACT may include a first source/drain region cSD1, a second source/drain region cSD2 disposed at a level different from a level of the first source/drain region cSD1, and a vertical channel region cCH between the first and second source/drain regions cSD1 and cSD2. The first source/drain region cSD1 may be disposed at a level higher than a level of the second source/drain region cSD2. The cell active patterns cACT may also be referred to as a cell semiconductor layer or a vertical channel layer.

The first source/drain region cSDc1, the second source/drain region cSD2, the vertical channel region cCH, the wordline WL facing a side surface of the vertical channel region cCH, and the gate dielectric layer cGO between the cell active pattern cACT and the wordline WL may be included in the cell transistor cTR. In an example implementation, the cell transistor cTR may be referred to as a vertical channel transistor. In the wordline WL, a portion facing the vertical channel region cCH may be configured as a gate electrode. The gate dielectric layer cGO may be in contact with a side surface of the cell active pattern cACT of the vertical channel region cCH, and a gate electrode portion of the wordline WL may be in contact with the gate dielectric layer cGO.

The back gate line BG may be in contact with a side surface of the vertical channel region cCH. The back gate dielectric layer cBO may be disposed between the back gate line BG and the vertical channel region cCH. The vertical channel region cCH may be disposed between the back gate line BG and the wordline WL. A pair of cell active patterns cACT adjacent to each other may be disposed between a pair of wordlines WL adjacent to each other, and the back gate line BG may be disposed between a pair of cell active patterns cACT adjacent to each other. The back gate line BG may be a back gate electrode.

The back gate line BG may control charges accumulated in the vertical channel region cCH. The vertical channel region cCH may be a floating body disposed between the first and second source/drain regions cSD1 and cSD2, and the back gate line BG may suppress or prevent performance of the cell transistor cTR from being degraded by the floating body effect, and may improve performance of the cell transistor cTR. For example, the back gate line BG may reduce or prevent a threshold voltage of the cell transistor cTR from changing due to charges, for example, holes, accumulating in the floating body of the vertical channel region cCH during operation of the cell transistor cTR.

The wordlines WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, but an example implementation thereof is not limited thereto. Each of the wordlines WL may include a single layer or multiple layers formed of the aforementioned conductive materials. The back gate lines BG may include at least one conductive material. For example, each of the back gate lines BG may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, but an example implementation thereof is not limited thereto. Each of the back gate lines BG may include a single layer or multiple layers formed of the materials described above.

The first structure ST1’ may further include contact structures 121 electrically connecting the second source/drain regions cSD2 to the first electrodes 127.

Each of the contact structures 121 may include a plug portion 112 in contact with the cell active pattern cACT and a pad portion 118 below the plug portion 112. The data storage structures DS may be disposed below the pad portions 118.

The bitlines BL may be connected to the cell active patterns cACT on the cell active patterns cACT. For example, the bitlines BL may be electrically connected to the first source/drain regions cSD1 of the cell active patterns cACT. Accordingly, the bitlines BL may be electrically connected to the cell transistors cTR.

Each of the bitlines BL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, but an example implementation thereof is not limited thereto. Each of the bitlines BL may include a single layer or multiple layers formed of the aforementioned conductive materials. For example, each of the bitlines BL may include a first conductive layer 150 and a second conductive layer 152 on the first conductive layer 150. The first conductive layer 150 may include doped silicon, and the second conductive layer 152 may include a conductive material having a resistivity lower than a resistivity of the doped silicon among the aforementioned conductive materials.

The first structure ST1’ may further include a shield conductive structure SL disposed in an upper portion of the bitlines BL. The shield conductive structure SL may include a portion having a plate shape. The shield conductive structure SL may be spaced apart from the bitlines BL. The shield conductive structure SL may screen capacitive coupling between the bitlines BL. For example, by reducing or blocking parasitic capacitance between the bitlines BL, the shield conductive structure SL may reduce resistive-capacitive delay (RC delay) of the bitlines BL.

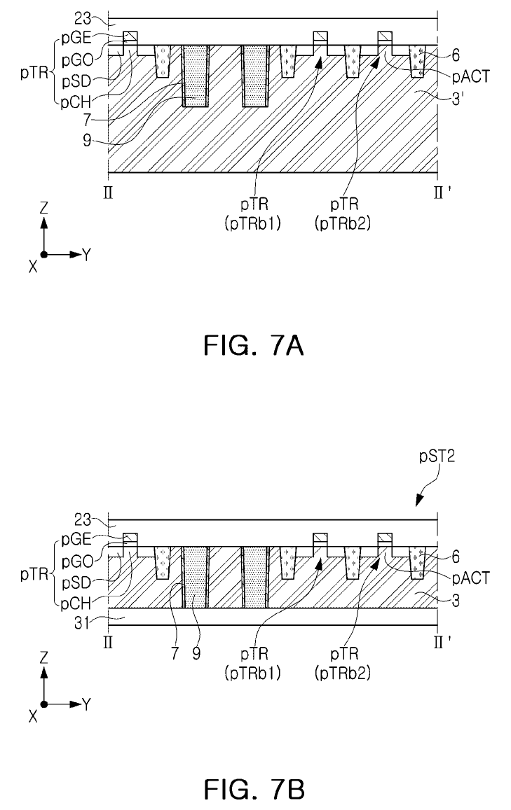

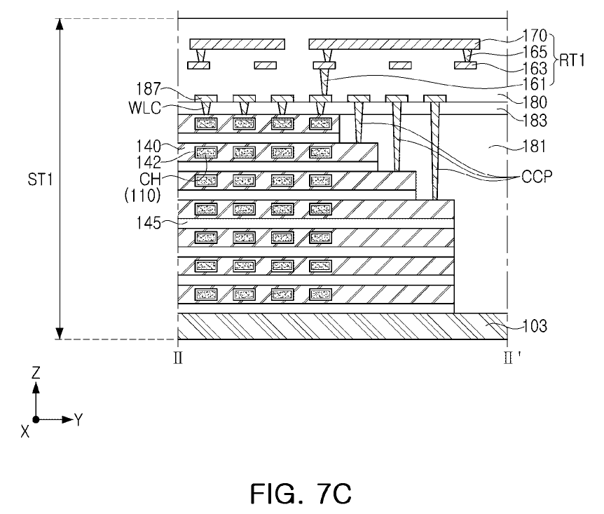

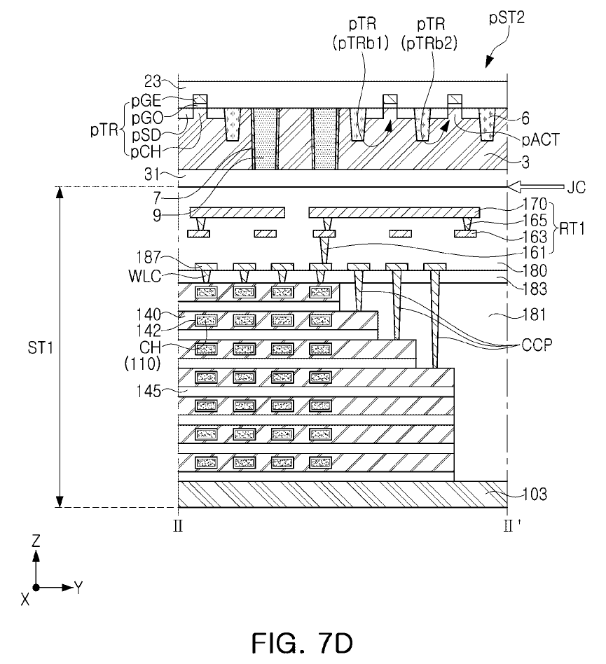

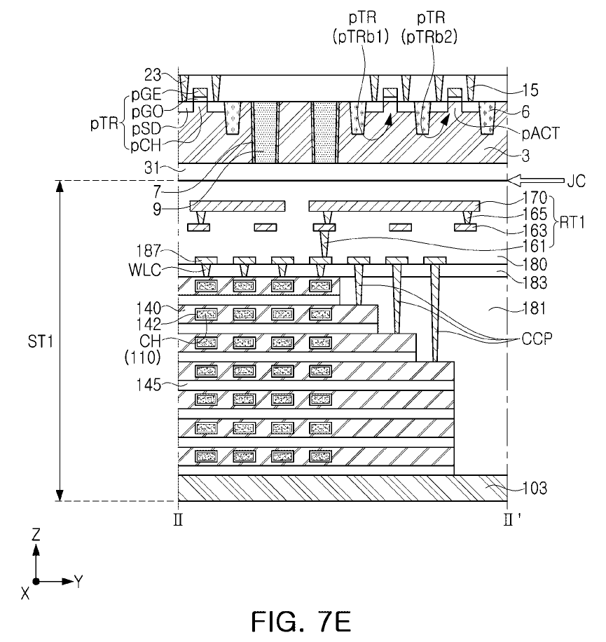

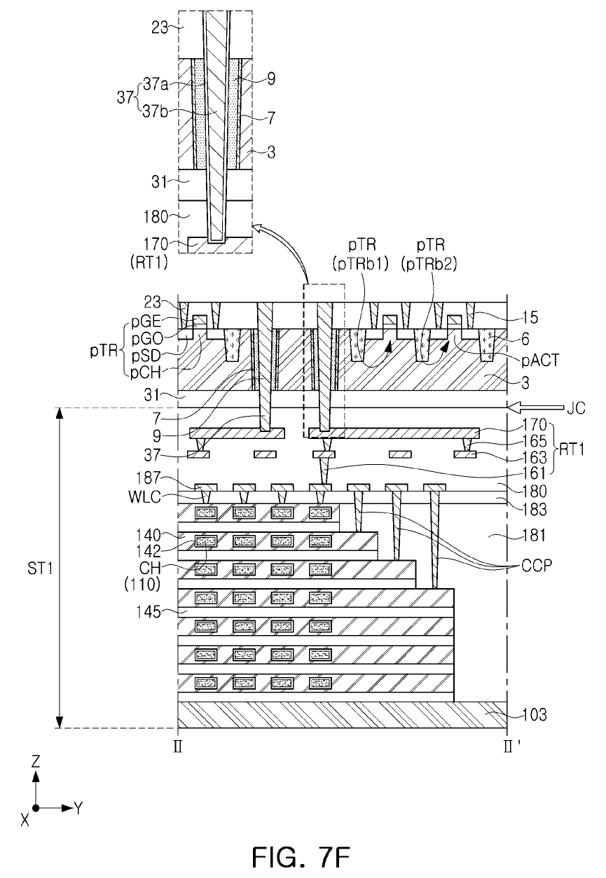

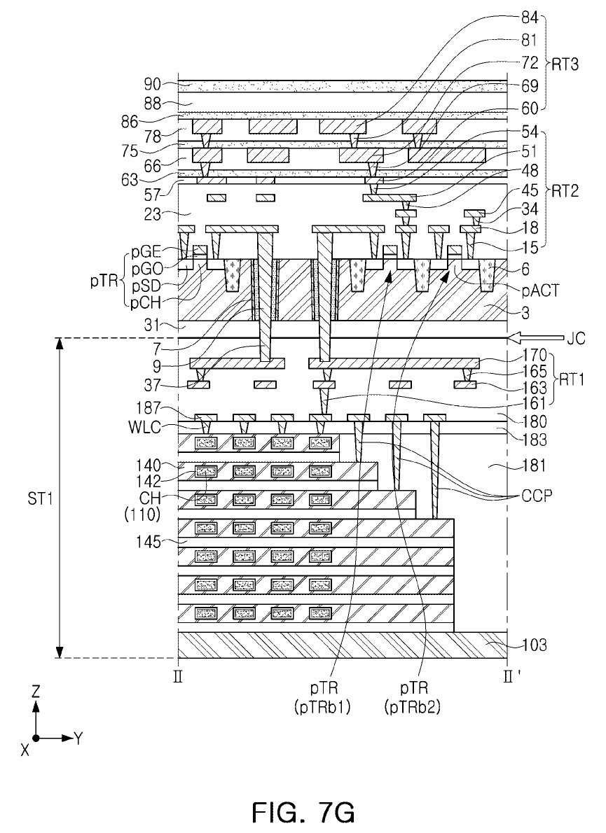

FIGS. 7A-7G are vertical cross-sectional diagrams illustrating processes of a method of manufacturing a semiconductor device in order according to an example implementation. FIGS. 7A-7G are cross-sectional diagrams illustrating a region taken along line II-II’ in FIG. 1A.

Referring to FIG. 7A, a device isolation region 6 defining peripheral active regions pACT may be formed on a substrate 3’. An opening penetrating at least a portion of the substrate 3’ may be formed. An insulating liner 7 may be formed on a sidewall of the opening, and through-insulating patterns 9 filling the opening may be formed. Lower surfaces of the through-insulating patterns 9 may be formed at a level lower than a level of a lower surface of the device isolation region 6. In an example implementation, the insulating liner 7 may be formed along asidewall and a lower surface of the opening (see FIG. 2).

Peripheral transistors pTR may be formed on the substrate 3’. Each of the peripheral transistors pTR may include peripheral source/drain regions pSD formed in the peripheral active region pACT, a peripheral channel region pCH between the peripheral source/drain regions pSD, and peripheral gates pGO and pGE on the peripheral channel region pCH. The peripheral gates pGO and pGE may include the peripheral gate dielectric layer pGO and the peripheral gate electrode pGE on the peripheral gate dielectric layer pGO.

The insulating structure 23 covering the peripheral transistors pTR may be formed on the substrate 2.

Referring to FIG. 7B, a semiconductor body 3 may be formed by reducing a thickness of the substrate (3’ in FIG. 7A) until the through-insulating patterns 9 are exposed. For example, by grinding a lower surface of the substrate (3’ in FIG. 7A), the semiconductor body 3 having a thickness less than a thickness of the substrate (3’ in FIG. 7A) may be formed. While forming the semiconductor body 3, the through-insulating patterns 9 may be exposed. For example, in the grinding process for reducing the thickness of the substrate (3’ in FIG. 7A), the through-insulating patterns 9 may work as a stopper.

A backside insulating layer 31 may be formed on an exposed surface of the semiconductor body 3 and an exposed surface of the through-insulating patterns 9. The exposed surface of the semiconductor body 3 and the exposed surface of the through-insulating patterns 9 may be in contact with the backside insulating layer 31. Accordingly, a second preliminary structure pST2 may be formed.

Referring to FIG. 7C, a first structure ST1 including a memory cell, a routing lower structure RT1 electrically connected to the memory cell, and an insulating structure 180 covering the routing lower structure RT1 may be formed. The order in which the first structure ST1 and the second preliminary structure pST2 are formed is not limited thereto. For example, after the first structure ST1 is formed, the second preliminary structure pST2 may be formed.

Referring to FIGS. 1B, 1D and 7C together, the memory cell may include channel structures 110 extending in a first horizontal direction (X-direction) and spaced apart from each other in a second horizontal direction (Y-direction) intersecting the first horizontal direction, bitlines 160 extending in a vertical direction and in contact with a first end of each of the channel structures 110, gate electrodes 140 extending in the second horizontal direction and surrounding the channel structures, data storage structures in contact with second ends of the channel structures 110 opposing the first ends of the channel structures 110 and spaced apart from each other in the second horizontal direction, and plate electrode PP connected to the data storage structures and extending in the second horizontal direction and the vertical direction. The gate electrodes 140 may be alternately stacked with interconnector insulating layers 145 in a vertical direction (Z-direction).

Thereafter, insulating layers 181 and 183 covering the memory cell may be formed, and contacts WLC and CCP penetrating the insulating layer 183 and electrically connected to the gate electrodes 140 may be formed, and a conductive line 187 may be formed on the contacts WLC and CCP.

Thereafter, an insulating structure 180 covering the conductive line 187 may be formed. A routing lower structure RT1 including first vertical vias 161 connected to the conductive line 187, first horizontal portions 163 on the first vertical vias 161, second vertical vias 165 connected to the first horizontal portions 163, and second horizontal portions 170 on the second vertical vias 165 may be formed. The insulating structure 180 may include a plurality of layers.

Referring to FIG. 7D, the second preliminary structure pST2 described with reference to FIG. 7B may be formed on the first structure ST1.

By performing a wafer bonding process, the first insulating structure 180 of the first structure ST1 and the backside insulating layer 31 of the second preliminary structure pST2 may be bonded to and in contact with each other. The bonding surface JC may be formed as the first insulating structure 180 and the backside insulating layer 31 are bonded to each other.

Referring to FIG. 7E, vertical plugs 15 may be formed.

Vertical plugs 15 penetrating the insulating structure 23 and electrically connected to the peripheral source/drain regions pSD may be formed.

Referring to FIG. 7F, a routing connection structure 37 penetrating the through-insulating pattern 9 may be formed.

An opening penetrating the second insulating structure 23, the through-insulating pattern 9, the backside insulating layer 31, and the first insulating structure 180 and exposing at least a portion of the horizontal portions 170 may be formed. A conductive barrier layer 37amay be formed on the inner sidewall of the opening, and a conductive material may be filled in the opening, thereby forming a conductive pillar 37b.

Referring to FIG. 7G, first and second routing peripheral structures RT2 and RT3 may be formed.

A first routing peripheral structure RT2 including first horizontal portions 18 on through-via 37 and vertical plugs 15, first vertical vias 34 connected to the first horizontal portions 18, second horizontal portions 45 on the first vertical vias 34, second vertical vias 48 connected to the second horizontal portions 45, third horizontal portions 51 on the second vertical vias 48, and third vertical vias 54 connected to the third horizontal portions 51 may be formed. The first routing peripheral structure RT2 may be buried in the second insulating structure 23.

A second routing peripheral structure RT3 and insulating layers 57, 63, 66, 75, and 78 covering side surfaces of the second routing peripheral structure RT3 may be formed on the first routing peripheral structure RT2.

The second routing peripheral structure RT3 may include first horizontal portions 60, first vertical vias 69 on the first horizontal portions 60, second horizontal portions 72 on the first vertical vias 69, third vertical vias 81 on the second horizontal portions 72, and fourth horizontal portions 84 on the third vertical vias 81.

The insulating layers 86, 88, and 90 stacked in order may be formed on the second routing peripheral structure RT3.

Thereafter, upper vias 93 penetrating the insulating layers 86, 88, and 90 may be formed, and upper interconnections 96 may be formed on the upper vias 93 (see FIG. 1D).

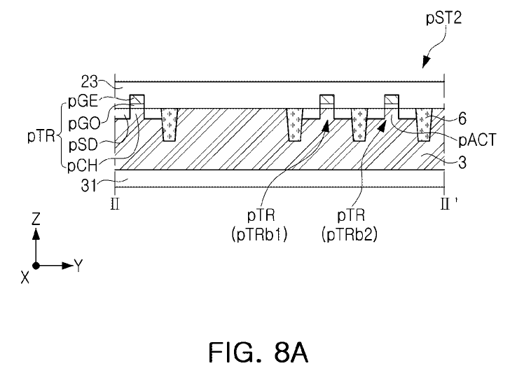

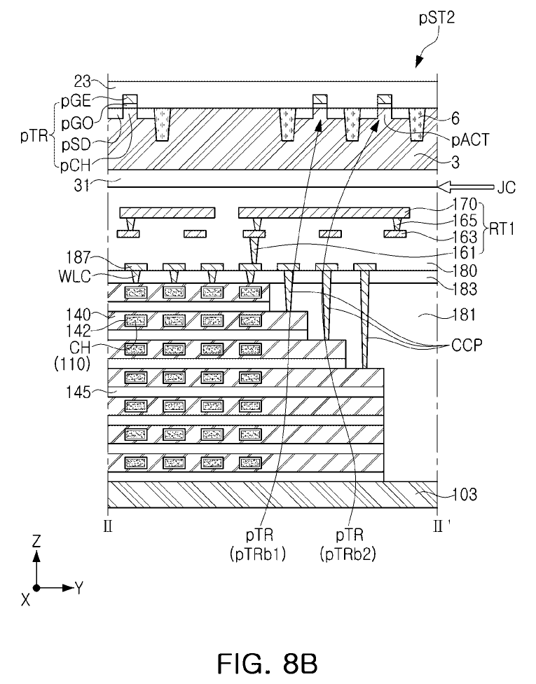

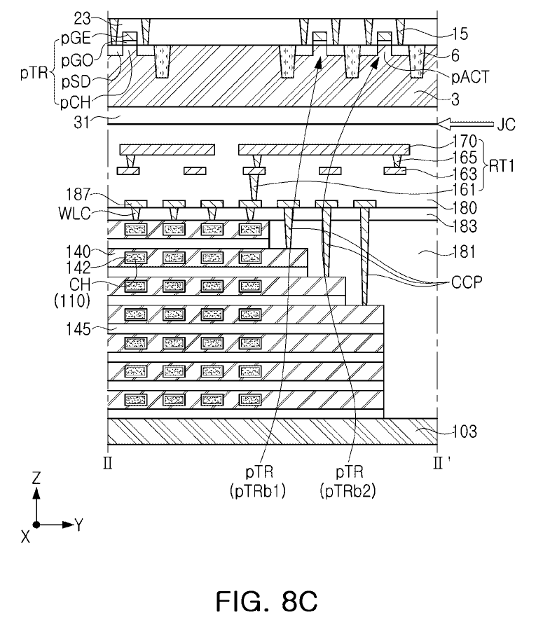

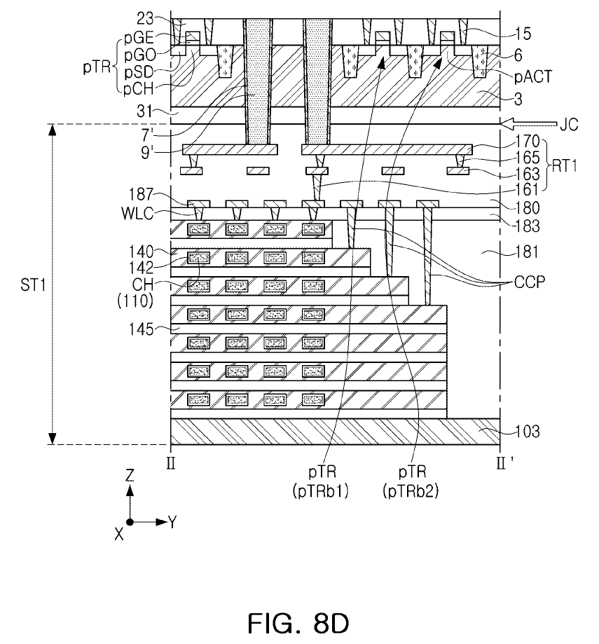

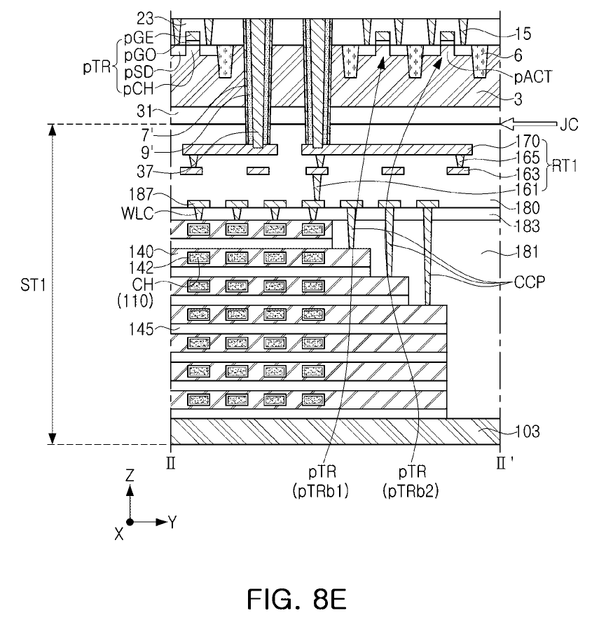

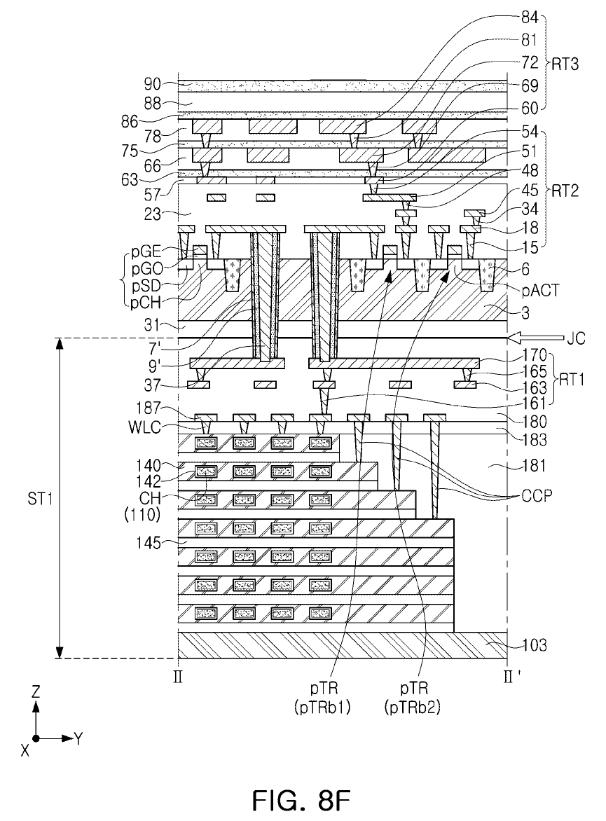

FIGS. 8A-8F are vertical cross-sectional diagrams illustrating processes of a method of manufacturing a semiconductor device in order according to an example implementation. FIGS. 8A-8F are vertical cross-sectional diagrams corresponding to FIG. 3A.

Referring to FIG. 8A, a device isolation region 6 defining peripheral active regions pACT may be formed on a substrate. Peripheral transistors pTR may be formed on the substrate. Each of the peripheral transistors pTR may include peripheral source/drain regions pSD formed in the peripheral active region pACT, peripheral channel region pCH between the peripheral source/drain regions pSD, and peripheral gates pGO and pGE on the peripheral channel region pCH. The peripheral gates pGO and pGE may include a peripheral gate dielectric layer pGO and a peripheral gate electrode pGE on the peripheral gate dielectric layer pGO.

An insulating structure 23 covering the peripheral transistors pTR may be formed on the substrate 2.

A semiconductor body 3 may be formed. For example, by grinding a lower surface of the substrate, the semiconductor body 3 may be formed. A backside insulating layer 31 may be formed on a lower surface of the semiconductor body 3. Accordingly, the second preliminary structure pST2 may be formed.

Referring to FIG. 8B, the first structure ST1 may be formed, and the second preliminary structure pST2 may be formed on the first structure ST1.

The first structure ST1 may be formed similarly to the example implementation described in FIG. 7C. By performing a wafer bonding process, the first insulating structure 180 of the first structure ST1 and the backside insulating layer 31 of the second preliminary structure pST2 may be bonded to and in contact with each other. The bonding surface JC may be formed as the first insulating structure 180 and the backside insulating layer 31 are bonded to each other.

Referring to FIG. 8C, vertical plugs 15 may be formed.

Vertical plugs 15 penetrating the insulating structure 23 and electrically connected to the peripheral source/drain regions pSD may be formed.

Referring to FIG. 8D, through-insulating patterns 9’ may be formed.

An opening penetrating the insulating structure 23, the semiconductor body 3, the backside insulating layer 31, and the insulating structure 180 and exposing at least a portion of the horizontal portion 170 may be formed. An insulating liner 7’ may be formed on a sidewall of the opening, and a through-insulating pattern 9’ filling the opening may be formed. In an example implementation, the insulating liner 7’ may be formed along a sidewall and a lower surface of the opening (see FIG. 4).

Referring to FIG. 8E, a routing connection structure 37 penetrating the through-insulating pattern 9’ may be formed.

An opening penetrating the through-insulating pattern 9’ and exposing at least a portion of the horizontal portions 170 may be formed. A conductive barrier layer 37a may be formed on an inner sidewall of the opening, and a conductive pillar 37b may be formed by filling the opening with a conductive material.

Referring to FIG. 8F, first and second routing peripheral structures RT2 and RT3 may be formed.

A first routing peripheral structure RT2 including first horizontal portions 18 on through-via 37 and vertical plugs 15, first vertical vias 34 connected to the first horizontal portions 18, second horizontal portions 45 on the first vertical vias 34, second vertical vias 48 connected to the second horizontal portions 45, third horizontal portions 51 on the second vertical vias 48, and third vertical vias 54 connected to the third horizontal portions 51 may be formed. The first routing peripheral structure RT2 may be buried in the second insulating structure 23.

The insulating layers 57, 63, 66, 75, and 78 covering side surfaces of the second routing peripheral structure RT3 and the second routing peripheral structure RT3 may be formed on the first routing peripheral structure RT2.

The second routing peripheral structure RT3 may include first horizontal portions 60, first vertical vias 69 on the first horizontal portions 60, second horizontal portions 72 on the first vertical vias 69, third vertical vias 81 on the second horizontal portions 72, and fourth horizontal portions 84 on the third vertical vias 81.

The insulating layers 86, 88, and 90 stacked in order on the second routing peripheral structure RT3 may be formed.

Thereafter, upper vias 93 penetrating the insulating layers 86, 88, and 90 may be formed, and upper interconnections 96 may be formed on the upper vias 93 (see FIG. 3A).

According to an example implementation of the present disclosure, a method of manufacturing a semiconductor device including forming a first structure including a memory cell, a routing lower structure electrically connected to the memory cell, and a first insulating structure covering the routing lower structure; forming a second preliminary structure including a peripheral circuit, wherein the forming the second preliminary structure includes forming a semiconductor body, forming a device isolation region defining a peripheral active region on the semiconductor body, forming an opening penetrating at least a portion of the semiconductor body, forming an insulating liner including a liner portion on a sidewall of the opening and a through-insulating pattern filling the opening, forming a peripheral transistor including a first peripheral source/drain disposed in the peripheral active region, a second peripheral source/drain, a peripheral channel region between the first and second peripheral sources/drains, and a peripheral gate disposed on the peripheral channel region, forming a second insulating structure covering the peripheral transistor, and forming a backside insulating layer below the semiconductor body; forming the second preliminary structure on the first structure; forming a routing connection structure penetrating the through-insulating pattern and electrically connected to the routing lower structure of the first structure; and forming a routing peripheral structure electrically connecting the peripheral transistor to the routing connection structure on the semiconductor body.

The forming the second preliminary structure on the first structure may include forming the backside insulating layer of the second preliminary structure on an upper surface of the first insulating structure of the first structure.

The routing connection structure may include a through-via, and the through-via may include a conductive pillar; and a conductive barrier layer covering a side surface and a lower surface of the conductive pillar.

The routing connection structure may penetrate a second insulating structure, the through-insulating pattern, the backside insulating layer, and the first insulating structure.

An upper surface of the routing connection structure may be disposed at a level higher than a level of an upper surface of the semiconductor body and a level of an upper surface of the through-insulating pattern, and a lower surface of the routing connection structure may be disposed at a level lower than a level of a lower surface of the semiconductor body and a level of a lower surface of the through-insulating pattern.

An upper surface of the insulating liner may be substantially coplanar with an upper surface of the semiconductor body and an upper surface of the through-insulating pattern, and a lower surface of the insulating liner may be substantially coplanar with a lower surface of the semiconductor body and a lower surface of the through-insulating pattern.

The insulating liner may further include an extension portion extending from an end of the liner portion between a lower surface of the through-insulating pattern and an upper surface of the backside insulating layer and in contact with a side surface of the routing connection structure.

The insulating liner may be selected from a group consisting of hafnium oxide, zirconium oxide, aluminum oxide, cerium oxide, gadolinium oxide, silicon nitride, and silicon nitride.

The memory cell of the first structure may include channel structures extending in a first horizontal direction and spaced apart from each other in a second horizontal direction intersecting the first horizontal direction; an insulating pattern between the channel structures; bitlines extending in a vertical direction and in contact with a first end of each of the channel structures; gate electrodes extending in the second horizontal direction and surrounding the channel structures; data storage structures in contact with second ends of the channel structures opposing the first ends of the channel structures and spaced apart from each other in the second horizontal direction; and a plate electrode connected to the data storage structures and extending in the second horizontal direction and the vertical direction, and wherein the bitlines may be electrically connected to the routing lower structure.

According to an example implementation of the present disclosure, a method of manufacturing a semiconductor device includes forming a first structure including a memory cell, a routing lower structure electrically connected to the memory cell, and a first insulating structure covering the routing lower structure; forming a second preliminary structure including a peripheral circuit, wherein the forming the second preliminary structure includes forming a semiconductor body, forming a device isolation region defining a peripheral active region on the semiconductor body, forming a peripheral transistor including a first peripheral source/drain disposed in the peripheral active region, a second peripheral source/drain, a peripheral channel region between the first and second peripheral sources/drains, and a peripheral gate disposed on the peripheral channel region, forming a second insulating structure covering the peripheral transistor, and forming a backside insulating layer below the semiconductor body; forming a second preliminary structure on the first structure; forming an opening penetrating at least a portion of the second preliminary structure and the first structure such that at least a portion of the routing lower structure is exposed; forming an insulating liner including a liner portion on a sidewall of the opening and a through-insulating pattern filling the opening; and forming a routing connection structure penetrating the through-insulating pattern and electrically connected to the routing lower structure of the first structure.

According to the aforementioned example implementations, a semiconductor device having improved reliability and performance may be provided.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

As used herein, “about,” “approximately,” “generally,” and “substantially” are understood to refer to numbers in a range of numerals, for example the range of -10% to +10% of the referenced number, preferably -5% to +5% of the referenced number, more preferably -1% to +1% of the referenced number, most preferably -0.1% to +0.1% of the referenced number.

While the example implementations have been illustrated and described above, it will be configured as apparent to those skilled in the art that modifications and variations could be made without departing from the scope of the present disclosure as defined by the appended claims.

What is claimed is:

1. A semiconductor device comprising:
a first structure including:
a memory cell,
a routing lower structure electrically connected to the memory cell, and
a first insulating structure covering the routing lower structure;
a second structure vertically overlapping the first structure and including a peripheral circuit, the second structure including:
a semiconductor body,
a backside insulating layer below the semiconductor body,
a device isolation region defining a peripheral active region on the semiconductor body,
a through-insulating pattern including a first pattern portion extending into the semiconductor body,
an insulating liner including a first liner portion disposed between the semiconductor body and the first pattern portion of the through-insulating pattern,
a peripheral transistor including a first peripheral source/drain disposed in the peripheral active region, a second peripheral source/drain, a peripheral channel region between the first peripheral source/drain and the second peripheral source/drain, and a peripheral gate disposed on the peripheral channel region,
a routing peripheral structure electrically connected to the peripheral transistor on the semiconductor body, and
a second insulating structure covering the routing peripheral structure; and
a routing connection structure electrically connecting the routing lower structure of the first structure to the routing peripheral structure of the second structure,
wherein the routing connection structure includes a through-via extending into the semiconductor body.

2. The semiconductor device of claim 1,
wherein the through-via extends into the through-insulating pattern,
wherein an upper surface of the through-via is disposed higher than an upper surface of the semiconductor body and an upper surface of the through-insulating pattern, and
wherein a lower surface of the through-via is disposed lower than a lower surface of the semiconductor body and a lower surface of the through-insulating pattern.

3. The semiconductor device of claim 1, wherein the through-via includes:
a conductive pillar; and
a conductive barrier layer covering a side surface and a lower surface of the conductive pillar.

4. The semiconductor device of claim 1,
wherein an upper surface of the insulating liner is coplanar with an upper surface of the semiconductor body and an upper surface of the through-insulating pattern, and
wherein a lower surface of the insulating liner is coplanar with a lower surface of the semiconductor body and a lower surface of the through-insulating pattern.

5. The semiconductor device of claim 1, wherein the insulating liner includes a first extension portion extending from an end of the first liner portion to a region between a lower surface of the through-insulating pattern and an upper surface of the backside insulating layer, and wherein the first extension portion is in contact with a side surface of the through-via.

6. The semiconductor device of claim 1, wherein the through-insulating pattern includes a second pattern portion connected to the first pattern portion and extending into at least a portion of the first insulating structure and at least a portion of the second insulating structure.

7. The semiconductor device of claim 6, wherein at least a portion of the through-insulating pattern is in contact with the routing peripheral structure and the routing lower structure.

8. The semiconductor device of claim 6, wherein the insulating liner includes a second liner portion disposed between the second pattern portion of the through-insulating pattern and the first insulating structure, and between the second pattern portion of the through-insulating pattern and the second insulating structure.

9. The semiconductor device of claim 8, wherein at least a portion of the second liner portion is in contact with the routing peripheral structure and the routing lower structure.

10. The semiconductor device of claim 8, wherein the insulating liner includes a second extension portion extending from an end of the second liner portion to a region between a lower surface of the second insulating structure and an upper surface of the routing lower structure, and wherein the second extension portion is in contact with a side surface of the through-via.

11. The semiconductor device of claim 1, wherein the insulating liner comprises at least one of hafnium oxide, zirconium oxide, aluminum oxide, cerium oxide, gadolinium oxide, silicon nitride, or silicon nitride.

12. The semiconductor device of claim 1, wherein the semiconductor body of the second structure has a P-type conductivity.

13. The semiconductor device of claim 1,
wherein the memory cell of the first structure includes:
channel structures extending in a first horizontal direction and spaced apart from each other in a second horizontal direction intersecting the first horizontal direction;
an insulating layer between the channel structures;
bitlines extending in a vertical direction and in contact with a first end of each of the channel structures;
gate electrodes extending in the second horizontal direction and surrounding the channel structures;
data storage structures in contact with second ends of the channel structures opposing the first ends of the channel structures and spaced apart from each other in the second horizontal direction; and
a plate electrode connected to the data storage structures and extending in the second horizontal direction and the vertical direction, and
wherein the bitlines are electrically connected to the routing lower structure.

14. The semiconductor device of claim 1,
wherein the first structure includes a wordline electrically connected to the memory cell,
wherein the memory cell of the first structure includes:
a vertical channel transistor; and
a data storage structure,
wherein the vertical channel transistor includes:
a cell active pattern including a first cell source/drain region, a second cell source/drain region disposed at a level different from a level of the first cell source/drain region, and a vertical channel region between the first cell source/drain region and the second cell source/drain region;
a gate dielectric layer in contact with the vertical channel region of the cell active pattern; and
the wordline in contact with the gate dielectric layer, and
wherein the data storage structure includes a first electrode electrically connected to the second cell source/drain region, a dielectric layer on the first electrode, and a second electrode on the dielectric layer.

15. A semiconductor device comprising:
a first structure including a memory cell array region and a staircase region, the first structure including:
channel structures extending in a first horizontal direction on the memory cell array region and spaced apart from each other in a second horizontal direction intersecting the first horizontal direction,
an insulating layer between the channel structures,
bitlines extending in a vertical direction on the memory cell array region and in contact with a first end of each of the channel structures,
at least one gate electrode extending in the second horizontal direction and surrounding the channel structures,
data storage structures in contact with second ends of the channel structures opposing the first ends of the channel structures and spaced apart from each other in the second horizontal direction,
a plate electrode connected to the data storage structures and extending in the second horizontal direction and the vertical direction, and
a routing lower structure electrically connected to the bitlines;
a second structure vertically overlapping the first structure and including a peripheral circuit, the second structure including:
a semiconductor body,
a backside insulating layer below the semiconductor body,
a device isolation region defining a peripheral active region on the semiconductor body,
a through-insulating pattern extending into the semiconductor body,
an insulating liner between the semiconductor body and the through-insulating pattern,
a peripheral transistor including a first peripheral source/drain disposed in the peripheral active region, a second peripheral source/drain, a peripheral channel region between the first peripheral source/drain and second peripheral source/drain, and a peripheral gate disposed on the peripheral channel region,
a routing peripheral structure electrically connected to the peripheral transistor on the semiconductor body, and
a second insulating structure covering the routing peripheral structure; and
a routing through-via electrically connecting the routing lower structure of the first structure to the routing peripheral structure of the second structure, and extending into the through-insulating pattern.

16. The semiconductor device of claim 15,
wherein the at least one gate electrode includes a plurality of gate electrodes extending in the second horizontal direction and spaced apart from each other in the vertical direction, and
wherein the plurality of gate electrodes extend from the memory cell array region to the staircase region by different lengths.

17. The semiconductor device of claim 15, wherein the through-insulating pattern and the insulating liner include different materials.

18. A semiconductor device, comprising:
a first structure including:
a memory cell, and
a routing lower structure electrically connected to the memory cell,
a second structure vertically overlapping the first structure and including a peripheral circuit, the second structure including:
a semiconductor body,
a device isolation region defining a peripheral active region on the semiconductor body,
a peripheral transistor in the peripheral active region,
a through-insulating pattern extending into the semiconductor body,
an insulating liner between the semiconductor body and the through-insulating pattern, and
a routing peripheral structure electrically connected to the peripheral transistor on the semiconductor body; and
a routing through-via extending into the through-insulating pattern and electrically connected to the routing peripheral structure.

19. The semiconductor device of claim 18, comprising:
an upper interconnection on the second structure,
wherein the routing through-via is electrically connected to the upper interconnection and the routing peripheral structure.

20. The semiconductor device of claim 18, wherein the routing through-via electrically connects the routing lower structure to the routing peripheral structure.
